(19) United States
(12) Patent Application Publication
(10) Pub. No.: US 2024/0250070 A1
(43) Pub. Date: Jul. 25, 2024

(54) FACILITATOR DIES FOR HETEROGENEOUS DIE STACKS

(71) Applicant: International Business Machines Corporation, Armonk, NY (US)

(72) Inventors: Kyu-hyoun Kim, Chappaqua, NY (US); Arvind Kumar, Stamford, CT (US); Joshua M. Rubin, Albany, NY (US); John W. Golz, Hopewell Junction, NY (US); Mounir Meghelli, Tarrytown, NY (US)

(21) Appl. No.: 18/159,111

(22) Filed: Jan. 25, 2023

(51) Int. Cl. H01L 25/065; H01L 23/00; H01L 23/528; H01L 23/60; H01L 27/02; H10B 80/00

(52) U.S. Cl. CPC H01L 25/0657; H01L 23/5286; H01L 23/60; H01L 24/16; H01L 24/48; H01L 27/0248; H10B 80/00; H01L 2224/48147; H01L 2225/06541; H01L 2924/15311

(57) ABSTRACT

Embodiments of the present invention are directed to processing methods and resulting structures for three-dimensional integrated circuits (3D ICs) having facilitator dies in a hierarchical configuration. In a non-limiting embodiment, a method includes forming a plurality of stacked dies. The plurality of stacked dies includes a bottom die having a first die type, a plurality of upper dies having a second die type different than the first die type, and a facilitator die having a third die type different than the first die type and the second die type. At least one of a signal connection and a power distribution line are formed hierarchically between the bottom die, the plurality of upper dies, and the facilitator die.

### BACKGROUND

The present invention generally relates to fabrication methods and resulting structures for stacked semiconductor devices, and more specifically, to facilitator dies for heterogeneous die stacks.

In microelectronics a stacked semiconductor device, also referred to as a three-dimensional integrated circuit (3D IC), refers to an integrated circuit manufactured by stacking silicon wafers, chips, and/or dies and interconnecting them vertically so that they behave as a single, vertically integrated device to achieve performance improvements at reduced power and at smaller footprint than conventional two-dimensional (2D) processes. During the stacking process, often referred to as through silicon stacking (TSS), any number of chips and/or dies can be stacked to form the 3D IC. In such devices, through silicon vias (TSVs) serve as interconnects between the circuit layers.

Each circuit layer within the 3D IC architecture can be built with different processes, or even on different types of wafers. Notably, this flexibility means that components can be optimized to a much greater degree than if they were built together on a single wafer. Moreover, components with incompatible manufacturing requirements can be built separately and later combined in a single 3D IC.

### SUMMARY

Embodiments of the invention are directed to a method for providing a three-dimensional integrated circuit (3D IC) having facilitator dies in a hierarchical configuration. A non-limiting example of the method includes forming a plurality of stacked dies. The plurality of stacked dies includes a bottom die having a first die type, a plurality of upper dies having a second die type different than the first die type, and a facilitator die having a third die type different than the first die type and the second die type. At least one of a signal connection and a power distribution line are formed hierarchically between the bottom die, the plurality of upper dies, and the facilitator die. Connections between the bottom die and the facilitator die define a first hierarchical level and connections between the facilitator die and one or more of the plurality of upper dies define a second hierarchical level.

Embodiments of the invention are directed to a semiconductor structure. A non-limiting example of the semiconductor structure includes a plurality of stacked dies. The plurality of stacked dies includes a bottom die having a first die type, a plurality of upper dies having a second die type different than the first die type, and a facilitator die having a third die type different than the first die type and the second die type. At least one of a signal connection and a power distribution line are positioned hierarchically between the bottom die, the plurality of upper dies, and the facilitator die. Connections between the bottom die and the facilitator die define a first hierarchical level and connections between the facilitator die and one or more of the plurality of upper dies define a second hierarchical level.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1 depicts a cross-sectional view of a three-dimensional integrated circuit (3D IC) configured in accordance with one or more embodiments of the invention;

FIG. 2 depicts a block diagram of a facilitator die of FIG. 1 in accordance with one or more embodiments;

FIG. 3A depicts a cross-sectional view of a 3D IC having a first layout in accordance with one or more embodiments of the invention;

FIG. 3B depicts a cross-sectional view of a 3D IC having a second layout in accordance with one or more embodiments of the invention;

FIG. 3C depicts a cross-sectional view of a 3D IC having a third layout in accordance with one or more embodiments of the invention;

FIG. 3D depicts a cross-sectional view of a 3D IC having a fourth layout in accordance with one or more embodiments of the invention;

FIG. 4A depicts an example sequential integration flow for building a die group having one or more facilitator dies in accordance with one or more embodiments;

FIG. 4B depicts an example die group having a center facilitator die configuration in accordance with one or more embodiments;

FIG. 4C depicts an example die group having a bottom facilitator die configuration in accordance with one or more embodiments;

FIG. 4D depicts an example die group having a top facilitator die configuration in accordance with one or more embodiments;

FIG. 5A depicts an example two-step stacking integration flow for building a 3D IC in accordance with one or more embodiments;

FIG. 5B depicts an example multi-step stacking integration flow for building a 3D IC in accordance with one or more embodiments; and

FIG. 6 depicts a flow diagram illustrating a method according to one or more embodiments of the invention.

The diagrams depicted herein are illustrative. There can be many variations to the diagram or the operations described therein without departing from the spirit of the invention. For instance, the actions can be performed in a differing order or actions can be added, deleted or modified.

In the accompanying figures and following detailed description of the described embodiments of the invention, the various elements illustrated in the figures are provided with two or three-digit reference numbers. With minor exceptions, the leftmost digit(s) of each reference number correspond to the figure in which its element is first illustrated.

### DETAILED DESCRIPTION

It is understood in advance that although example embodiments of the invention are described in connection with a particular three-dimensional integrated circuit (3D IC) architecture, embodiments of the invention are not limited to the particular architecture layout described in this specification. Rather, embodiments of the present invention are capable of being implemented in conjunction with any of a number of 3D IC layouts having any number of devices now known or later developed distributed across any number of circuit layers.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the present invention, ICs are fabricated in a series of stages, including a front-end-of-line (FEOL) stage, a middle-of-line (MOL) stage, a back-end-of-line (BEOL) stage, and a far back end of line (FBEOL) stage. The process flows for fabricating modern ICs are often identified based on whether the process flows fall in the FEOL stage, the MOL stage, the BEOL stage, and/or the FBEOL stage. Generally, the FEOL stage is where device elements (e.g., transistors, capacitors, resistors, etc.) are patterned onto a semiconductor substrate/wafer. The FEOL stage processes include wafer preparation, isolation, gate patterning, and the formation of wells, source/drain (S/D) regions, extension junctions, silicide regions, and liners. The MOL stage typically includes process flows for forming the contacts (e.g., CA) and other structures that communicatively couple to active regions (e.g., gate, source, and drain) of the device element. For example, the silicidation of source/drain regions, as well as the deposition of metal contacts, can occur during the MOL stage to connect the elements patterned during the FEOL stage. Layers of interconnections (e.g., metallization layers) are formed above these logical and functional layers during the BEOL stage and off-chip wiring (e.g., under bump metals, redistribution layers, etc.) is incorporated during the FBEOL to complete the IC. Most ICs need more than one layer of wires to form all the necessary connections, and as many as 5-12 layers are added in the BEOL process. The various BEOL layers are interconnected by vias that couple from one layer to another. Insulating dielectric materials are used throughout the layers of an IC to perform a variety of functions, including stabilizing the IC structure and providing electrical isolation of the IC elements. For example, the metal interconnecting wires in the BEOL region of the IC are isolated by dielectric layers to prevent the wires from creating a short circuit with other metal layers.

Generally, current 3D IC designs rely on a single bottom die, commonly referred to as a type-1 die, and a plurality of homogeneous upper dies, commonly referred to as type-2 dies. The type-1 die is not homogenous with the type-2 dies. Signal connections and power distribution are fly-by. As used herein, a “fly-by” topology refers to an arrangement whereby a command signal, an address signal, and a clock signal are supplied through one wire to each of the memory devices of the 3D IC. Unfortunately, such 3D IC configurations are natively limited in total stack size (number of layers) by run (wire) lengths, latency and voltage drop considerations, as each die is serviced from a same wire connected back to the bottom (type-1) die. In other words, the connectivity burden for each fly-by wire increases directly with an increase in circuit layers (i.e., number of stacked dies).

Turning now to an overview of aspects of the present invention, one or more embodiments of the invention address the above-described shortcomings by providing fabrication methods and resulting structures that leverage one or more facilitator dies within a heterogeneous die stack in a 3D IC layout. As used herein, a “facilitator die” refers to a so-called type-3 die which can be incorporated along with the type-2 upper dies into a die stack, and which serves as a hierarchical contact layer for signal connections and/or power distribution between the type-1 die and the type-2 dies.

Advantageously, configuring a 3D IC in this manner allows for arbitrary stack heights largely decoupled from fly-by wire requirements. For example, 16 layer, 32, layer, 64 layer (or even 128 layer, 256 layer, etc.) stack heights can be hierarchically serviced by distributing one or more facilitator (type-3) dies throughout a stack. In some embodiments, the type-3 dies are heterogenous to the type-2 and/or type-3 dies. Notably, the facilitator dies can be flexibly located at any desired layer of the stack depending on the needs of a particular application. For example, a facilitator die can be located at the bottom of the stack (e.g., as the first non type-1 die), the top of the stack (e.g., as the topmost upper die), at common intervals (e.g., at ¼, ½, ¾, of the stack height), or at asymmetrical intervals (e.g., all at the top, or bottom, etc.) throughout the stack.

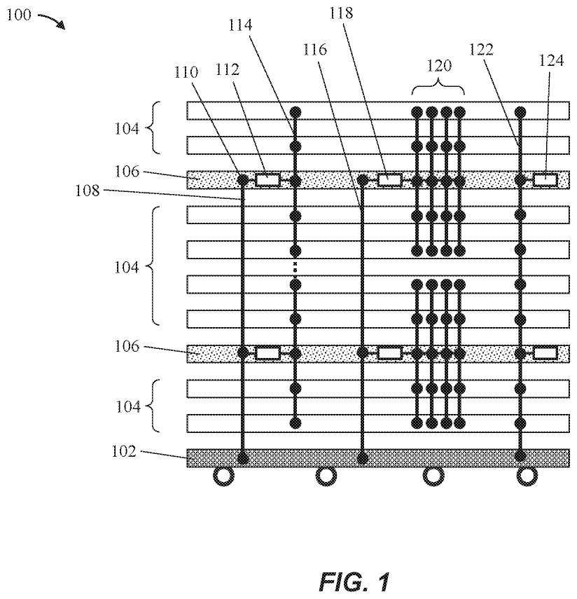

Turning now to a more detailed description of fabrication operations and resulting structures according to aspects of the invention, FIG. 1 depicts a cross-sectional view of a 3D IC 100 configured in accordance with one or more embodiments. In some embodiments, the 3D IC 100 includes a bottom die 102 (also referred to as an interface die), a plurality of upper dies 104 (also referred to as core dies), and one or more facilitator dies 106. In some embodiments, the 3D IC 100 includes 8 upper dies 104 and 2 facilitator dies 106, configured and arranged as shown in FIG. 1. Other 3D IC layouts, having any number of upper dies 104 and/or facilitator dies 106 are possible, and all such configurations are within the contemplated scope of this disclosure.

In some embodiments, the bottom die 102 is made of a first die type (e.g., type-1), the plurality of upper dies 104 are each made of a second die type (e.g., type-2), and the one or more facilitator dies 106 are each made of a third die type (e.g., type-2). In some embodiments, the first die type, the second die type, and/or the third die type are heterogeneous with respect to one or both of the other die types.

As further shown in FIG. 1, in some embodiments, the 3D IC 100 includes a global power line 108. In some embodiments, the global power line 108 is a high voltage power line. In some embodiments, the global power line 108 runs directly from the bottom die 102 to each of the one or more facilitator dies 106. In some embodiments, the global power line 108 is electrically coupled to the bottom die 102 and/or to each of the one or more facilitator dies 106 using a through silicon via (TSV) 110.

In some embodiments, each of the one or more facilitator dies 106 includes a voltage converter 112. In some embodiments, the voltage converter 112 is an on-chip voltage converter. In some embodiments, the voltage converter 112 is a voltage regulator. In some embodiments, the voltage converter 112 is electrically coupled to the global power line 108 by way of a TSV 110 (using, e.g., a wire, interconnect line, etc., not separately indicated).

In some embodiments, each of the voltage converters 112 is also electrically coupled to a local power line 114 by way of another TSV 110. In some embodiments, the local power line 114 is a low voltage power line. As used herein, a “low” voltage power line refers to a voltage lower than a voltage of the global power line 108. For example, in some embodiments, the global power line 108 is a 12 volt (12V) line and the local power line 114 is a 1 volt (1V) line (or 2V, 5V, etc.). In some embodiments, the local power line 114 runs from the respective one of the facilitator dies 106 to one or more of the upper dies 104. The local power line 114 can electrically couple to each of the upper dies 104 by way of a TSV 110.

As further shown in FIG. 1, in some embodiments, the 3D IC 100 includes a global signal line 116. In some embodiments, the global signal line 116 is a serial signal line. In some embodiments, the global signal line 116 runs directly from the bottom die 102 to each of the one or more facilitator dies 106. In some embodiments, the global signal line 116 is electrically coupled to the bottom die 102 and/or to each of the one or more facilitator dies 106 using a TSV 110.

In some embodiments, each of the one or more facilitator dies 106 includes a serializer/de-serializer 118. In some embodiments, the serializer/de-serializer 118 is an on-chip serializer/de-serializer. In some embodiments, the serializer/de-serializer 118 is electrically coupled to the global signal line 116 by way of a TSV 110.

In some embodiments, each of the serializer/de-serializers 118 is also electrically coupled to a local signal bus 120 by way of one or more of the TSVs 110. In some embodiments, the local signal bus 120 is a parallel signal line. In some embodiments, the local signal bus 120 runs from the respective one of the facilitator dies 106 to one or more of the upper dies 104. The local signal bus 120 can electrically couple to each of the upper dies 104 by way of a TSV 110.

As further shown in FIG. 1, in some embodiments, the 3D IC 100 includes a common signal line 122. In some embodiments, the common signal line 122 is a fly-by-signal line. In some embodiments, the common signal line 122 runs directly from the bottom die 102 to each of the one or more facilitator dies 106. In some embodiments, the common signal line 122 is electrically coupled to the bottom die 102 and/or to each of the one or more facilitator dies 106 using a TSV 110.

In some embodiments, each of the one or more facilitator dies 106 includes an electrostatic discharge (ESD) protection circuit 124. In some embodiments, the ESD protection circuit 124 is an on-chip ESD protection circuit. In some embodiments, the ESD protection circuit 124 is electrically coupled to the common signal line 122 by way of a TSV 110. In some embodiments, each of the ESD protection circuits 124 are further electrically coupled to one or more downstream fly-by-signal lines (not separately shown).

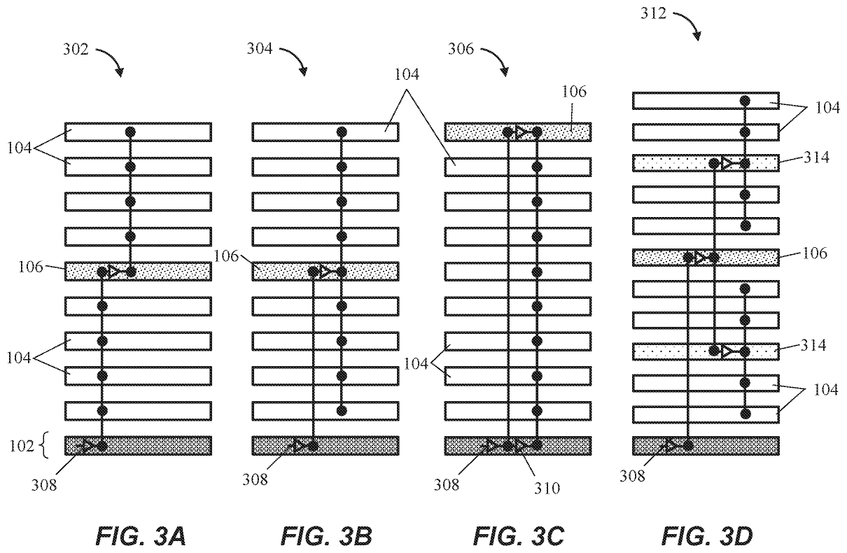

As shown in FIG. 1, configuring the 3D IC 100 to include one or more facilitator dies 106 allows for a hierarchical layout of the power (e.g., the global power line 108 and local power lines 114), signal (e.g., the global signal line 116 and the local signal buses 120), and common/fly-by signals (e.g., the common signal line 122). The 3D IC 100 shown in FIG. 1 depicts a two-hierarchy layout, where the bottom die 102 feeds the facilitator dies 106 (defining, e.g., the first hierarchal level) and the facilitator dies 106 each feed a separate subset of the upper dies 104 (defining, e.g., the second hierarchal level). It should be understood, however, that any number of hierarchical levels can be including in the 3D IC 100 by extending the layout with one or more additional facilitator dies (not separately shown) at each hierarchical level. For example, in a three-hierarchy layout the bottom die 102 can be replaced with an additional facilitator die that is itself fed by an upstream bottom die (refer, e.g., to FIG. 3D).

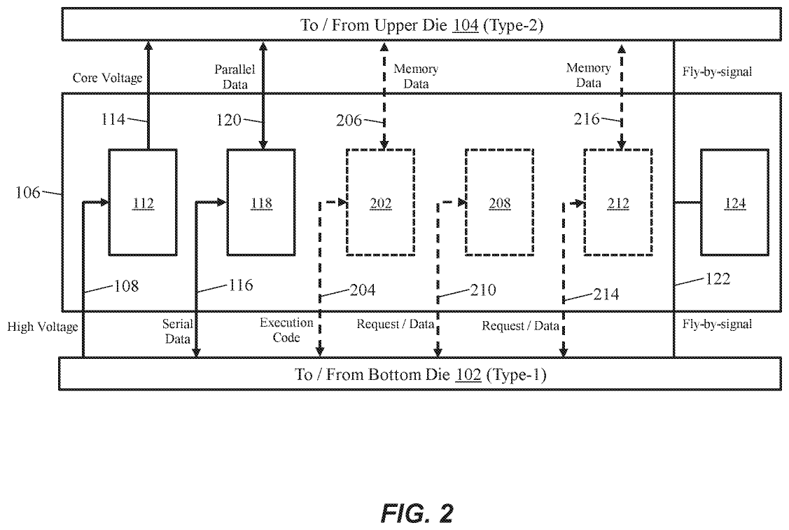

FIG. 2 depicts a block diagram of a facilitator die 106 of FIG. 1 in accordance with one or more embodiments. In some embodiments, the facilitator die 106 includes a voltage converter 112 (and/or regulator) servicing a global power line 108 and one or more local power lines 114. In some embodiments, the facilitator die 106 includes a serializer/de-serializer 118 servicing a global signal line 116 and one or more local signal buses 120. In some embodiments, the facilitator die 106 includes an ESD protection circuit 124 servicing a common signal line 122. Each of these components (e.g., power, signal, common—sometimes referred to as functional blocks) can be configured and arranged as discussed previously with respect to FIG. 1. The particular components shown in FIG. 2 are selected for ease of illustration and discussion only. It should be understood that each facilitator die 106 can include any subset (including all or none) of these functional blocks. Moreover, each facilitator die 106 can include a different subset (including all or none) of these functional blocks.

As further shown in FIG. 2, in some embodiments, the facilitator die 106 can include one or more additional functional blocks not separately shown in FIG. 1. For example, in some embodiments, the facilitator die 106 can include a near memory processor 202. In some embodiments, the near memory processor 202 is configured to receive an execution code 204 from the bottom die 102, to process the execution code 204, and to transmit memory data 206 to an upper die(s) 104.

In some embodiments, the facilitator die 106 can include a local memory 208. In some embodiments, the local memory 208 is an SRAM. In some embodiments, the local memory 208 is configured to receive data 210 (e.g., a request/data signal) from the bottom die 102 and to store the data 210.

In some embodiments, the facilitator die 106 can include a memory controller 212. In some embodiments, the memory controller 212 is configured to receive data 214 (e.g., a request/data signal) from the bottom die 102, to process the data 214, and to transmit memory data 216 to an upper die(s) 104.

The additional functional blocks shown in FIG. 2 are selected for ease of illustration and discussion only. It should be understood that each facilitator die 106 can include any subset (including all or none) of these additional functional blocks. Moreover, each facilitator die 106 can include a different subset (including all or none) of these additional functional blocks.

FIGS. 3A, 3B, 3C, and 3D depict various example functional block and wiring layouts for a 3D IC 100 configured in accordance with one or more embodiments. FIG. 3A depicts a cross-sectional view of a 3D IC 100 having a first layout 302 in accordance with one or more embodiments. In some embodiments, the first layout 302 is a redrive configuration (also referred to as a daisy-chain). In a redrive configuration, the bottom die 102 feeds a facilitator die 106 as well as a first portion of the plurality of upper dies 104, while the facilitator die 106 feeds a second portion of the plurality of upper dies 104. The final (terminal) die of the upper dies 104 can be replaced with another facilitator die (not separately shown) to continue the daisy-chain.

FIG. 3B depicts a cross-sectional view of a 3D IC 100 having a second layout 304 in accordance with one or more embodiments. In some embodiments, the second layout 304 is a two-level tree configuration. In a two-level tree configuration, the bottom die 102 feeds a facilitator die 106 and the facilitator die 106 feeds the plurality of upper dies 104. Any one (or more) of the upper dies 104 can be replaced with another facilitator die (not separately shown) to generate an N-level tree configuration (refer to FIG. 3D).

FIG. 3C depicts a cross-sectional view of a 3D IC 100 having a third layout 306 in accordance with one or more embodiments. In some embodiments, the third layout 306 is a both-end drive configuration. In a both-end drive configuration, a first functional block 308 (e.g., a voltage converter, serializer/de-serializer, signal repeater, or any other type of functional block) of the bottom die 102 feeds a facilitator die 106 and a second functional block 310 (e.g., a voltage converter, serializer/de-serializer, signal repeater, or any other type of functional block) of the bottom die 102 feeds the upper dies 104 from one end of the third layout 306. The facilitator die 106 feeds the upper dies 104 from the other end of the third layout 306.

FIG. 3D depicts a cross-sectional view of a 3D IC 100 having a fourth layout 312 in accordance with one or more embodiments. In some embodiments, the fourth layout 312 is a three-level tree configuration. In a three-level tree configuration, the bottom die 102 feeds a facilitator die 106 and the facilitator die 106 feeds one or more third hierarchy level facilitator dies 314. The third hierarchy level facilitator dies 314 feed the plurality of upper dies 104. Any one (or more) of the upper dies 104 can be replaced with additional hierarchy level facilitator dies (not separately shown) to generate an N-level tree configuration. The third (or higher) hierarchy level facilitator dies 314 can be of a same type (e.g., type-3), or different type (e.g., type-4, type-5, etc.) as the facilitator dies 106.

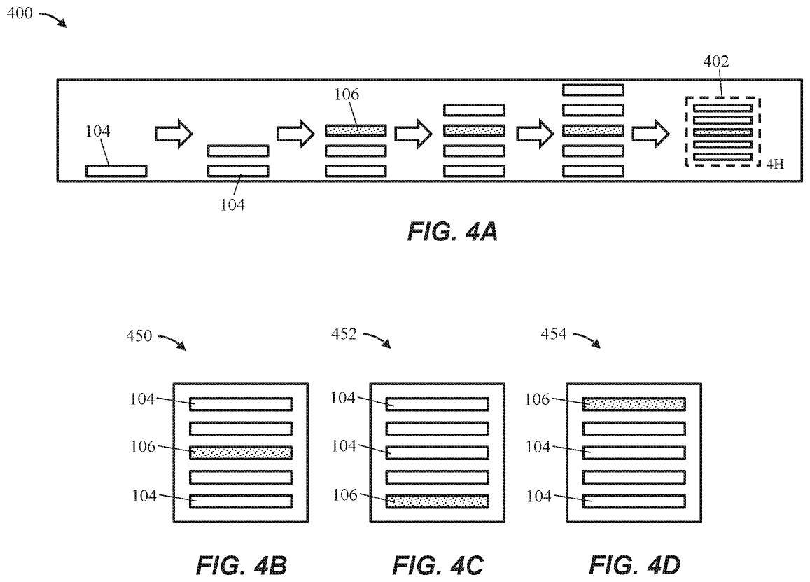

FIG. 4A depicts an example sequential integration flow 400 for building a die group having one or more facilitator dies (e.g., facilitator dies 106, third hierarchy level facilitator dies 314, and/or additional hierarchy level facilitator dies) in accordance with one or more embodiments. As shown in FIG. 4A, a die group 402 can be built via sequential stacking (i.e., layer by layer) of the upper dies 104 and facilitator dies (here, the facilitator die 106). The resultant die group 402 is shown having four upper dies 104 and a single facilitator die 106 in a so-called four height (4H) configuration. Observe that the “height” of a die group refers to the number of active layers (upper dies 104)—the facilitator dies do not contribute to the die group height. The number of upper dies 104 and facilitator dies 104 within the die group 402 is not meant to be particularly limited. Moreover, the relative location of the facilitator die(s) 104 within the die group 402 is not meant to be particularly limited, but is shown in FIG. 4A in a single, middle configuration.

FIGS. 4B, 4C, and 4D depict example die groups 450, 452, 454, respectively, configured in accordance with one or more embodiments. As shown in FIG. 4B, the facilitator die 106 can be placed in a center configuration. In some embodiments, the number of upper dies 104 above and below the facilitator die 106 can be the same (symmetrical center configuration), or different (asymmetrical center configuration). As shown in FIG. 4C, the facilitator die 106 can be placed in a bottom configuration. As shown in FIG. 4D, the facilitator die 106 can be placed in a top configuration.

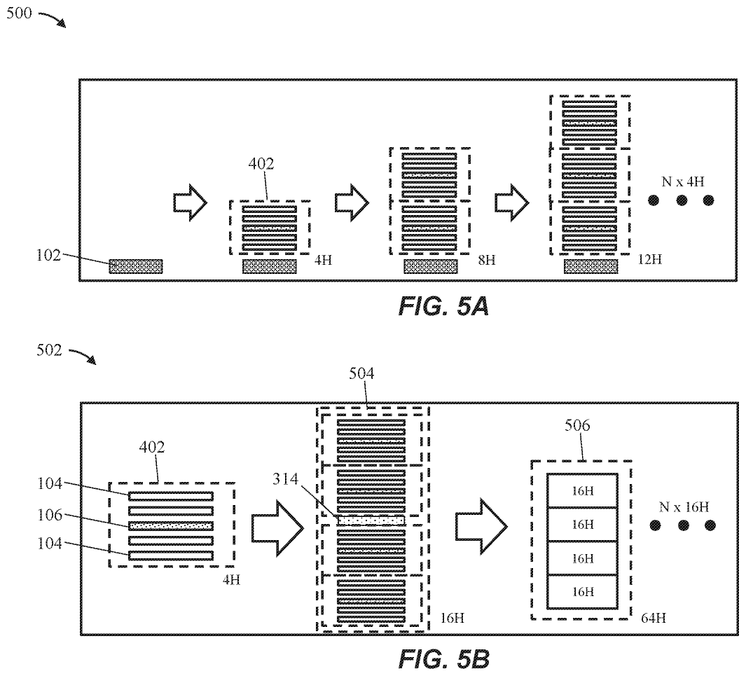

FIG. 5A depicts an example two-step stacking integration flow 500 for building a 3D IC 100 having one or more facilitator dies (e.g., facilitator dies 106, third hierarchy level facilitator dies 314, and/or additional hierarchy level facilitator dies) in accordance with one or more embodiments. In some embodiments, one or more die groups 402 can be separately built via, for example, sequential stacking (i.e., layer by layer), in a similar manner as described previously with respect to FIG. 4A. Building the die groups 402 can be referred to as a first stacking step. In some embodiments, the one or more die groups 402 can be stacked together over a bottom die 102. Stacking the die groups 402 can be referred to as a second stacking step.

FIG. 5A shows four-height die groups 402 (e.g., 4H) for ease of discussion and illustration only. In some embodiments, the 3D IC 100 is built from die groups 402 having any number of active layers (upper dies 104). In some embodiments, each of the die groups 402 can have a same, or a different, number of active layers. This two-step stacking process can be repeated arbitrarily to define 3D ICs 100 having any desired height. For example, N four-height die groups can be stacked to a height of N×4H (e.g., 4H, 8H, 12H, 16H, 20H, 40H, 60H, 120H, etc.).

FIG. 5B depicts an example multi-step stacking integration flow 502 for building a 3D IC 100 having one or more facilitator dies (e.g., facilitator dies 106, third hierarchy level facilitator dies 314, and/or additional hierarchy level facilitator dies) in accordance with one or more embodiments. In some embodiments, one or more die groups 402 can be separately built via, for example, sequential stacking (i.e., layer by layer), in a similar manner as described previously with respect to FIG. 4A. Building the die groups 402 can be referred to as a first stacking step.

In some embodiments, the one or more die groups 402 can be stacked together to define an intermediate die stack 504. Stacking the die groups 402 can be referred to as a second stacking step. As further shown in FIG. 5B, in some embodiments, the intermediate die stack 504 includes one or more third hierarchy level facilitator dies 314. In some embodiments, the third hierarchy level facilitator dies 314 serve to couple two or more of the die groups 402. FIG. 5B shows a 16-height (16H) intermediate die stack 504 having four die groups 402 and a single third hierarchy level facilitator die 314 for ease of discussion and illustration only. In some embodiments, the 3D IC 100 is built from an intermediate die stack 504 having any number of die groups 402. In some embodiments, each of the die groups 402 can have a same, or a different, number of active layers.

In some embodiments, the intermediate die stack 504 can be stacked together with one or more other intermediate die stacks 504 to define a final die stack 506. Stacking the intermediate die stacks 504 can be referred to as a third stacking step. FIG. 5B shows a 64-height (64H) final die stack 506 having four intermediate die stacks 504 for ease of discussion and illustration only. In some embodiments, the 3D IC 100 is built from a final die stack 506 having any number of intermediate die stacks 504. The third stacking step can be repeated arbitrarily to define 3D ICs 100 having any desired height. For example, N 16-height intermediate die stacks can be stacked to a height of N×16H (e.g., 16H, 32H, 48H, 64H, 80H, 96H, 112H, 128H, etc.).

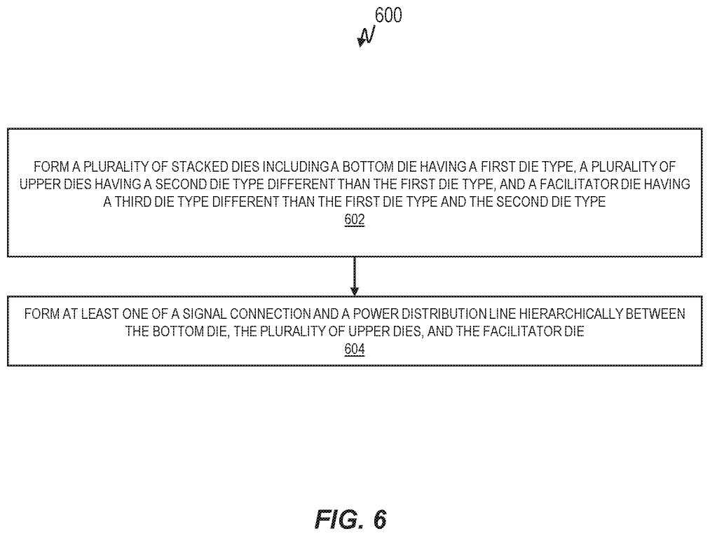

FIG. 6 depicts a flow diagram illustrating a method 600 for providing 3D ICs having facilitator dies according to one or more embodiments of the invention. The method 600 is described in reference to FIGS. 1 to 5B and may include additional steps not depicted in FIG. 6. Although depicted in a particular order, the blocks depicted in FIG. 6 can be rearranged, subdivided, and/or combined.

As shown at block 602, a plurality of stacked dies are formed. In some embodiments, the plurality of stacked dies include a bottom die having a first die type, a plurality of upper dies having a second die type different than the first die type, and a facilitator die having a third die type different than the first die type and the second die type.

At block 604, at least one of a signal connection and a power distribution line are positioned hierarchically between the bottom die, the plurality of upper dies, and the facilitator die. In some embodiments, connections between the bottom die and the facilitator die define a first hierarchical level. In some embodiments, connections between the facilitator die and one or more of the plurality of upper dies define a second hierarchical level. In some embodiments, the first hierarchical level and the second hierarchical level define a redrive configuration. In some embodiments, the first hierarchical level and the second hierarchical level define an N-level tree configuration (e.g., 2-level tree, 3-level tree, 8-level tree, etc.). In some embodiments, the first hierarchical level and the second hierarchical level define a both-end drive configuration.

The method can further include forming a global power line having a first voltage (e.g., 12V). In some embodiments, the global power line is coupled to the bottom die and the facilitator die in the first hierarchical level. In some embodiments, a local power line having a second voltage (e.g., 1V) less than the first voltage is coupled to the facilitator die and one or more of the plurality of upper dies in the second hierarchical level. In some embodiments, a voltage converter is formed on the facilitator die. In some embodiments, the voltage converter is coupled to the global power line and the local power line.

The method can include forming a global signal line coupled to the bottom die and the facilitator die in the first hierarchical level. In some embodiments, a local signal bus is coupled to the facilitator die and one or more of the plurality of upper dies in the second hierarchical level. In some embodiments, a serializer is formed on the facilitator die. In some embodiments, the serializer is coupled to the global signal line and the local signal bus.

The method can include forming a common signal line (e.g., a fly-by-signal). In some embodiments, the common signal line is coupled to the bottom die and the facilitator die in the first hierarchical level. In some embodiments, an ESD protection circuit is formed on the facilitator die. In some embodiments, the ESD protection circuit is coupled to the common signal line.

The method can include forming a near memory processor on the facilitator die. In some embodiments, the near memory processor is configured to receive an execution code from the bottom die, process the execution code, and transmit memory data to an upper die of the plurality of upper dies.

The method can include forming a local memory on the facilitator die. In some embodiments, the local memory is configured to receive request and data signals from the bottom die.

The method can include forming a memory controller on the facilitator die. In some embodiments, the memory controller is configured to receive data from the bottom die, process the data, and transmit memory data to an upper die of the plurality of upper dies.

The methods and resulting structures described herein can be used in the fabrication of IC chips. The resulting IC chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes IC chips, ranging from toys and other low-end applications to advanced computer products having a display, a keyboard or other input device, and a central processor.

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Similarly, the term “coupled” and variations thereof describes having a communications path between two elements and does not imply a direct connection between the elements with no intervening elements/connections between them. All of these variations are considered a part of the specification. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, are used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (e.g., rotated 90 degrees or at other orientations), and the spatially relative descriptors used herein should be interpreted accordingly.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), chemical-mechanical planarization (CMP), and the like. Reactive ion etching (RIE), for example, is a type of dry etching that uses chemically reactive plasma to remove a material, such as a masked pattern of semiconductor material, by exposing the material to a bombardment of ions that dislodge portions of the material from the exposed surface. The plasma is typically generated under low pressure (vacuum) by an electromagnetic field. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present invention. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present invention have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A method for forming a stacked semiconductor device, the method comprising:
forming a plurality of stacked dies, the plurality of stacked dies comprising:
a bottom die comprising a first die type;
a plurality of upper dies comprising a second die type different than the first die type; and
a facilitator die comprising a third die type different than the first die type and the second die type; and
forming at least one of a signal connection and a power distribution line hierarchically between the bottom die, the plurality of upper dies, and the facilitator die, wherein connections between the bottom die and the facilitator die comprise a first hierarchical level and connections between the facilitator die and one or more of the plurality of upper dies comprise a second hierarchical level.

2. The method of claim 1, further comprising:
forming a global power line comprising a first voltage, the global power line coupled to the bottom die and the facilitator die in the first hierarchical level;
forming a local power line comprising a second voltage less than the first voltage, the local power line coupled to the facilitator die and one or more of the plurality of upper dies in the second hierarchical level; and
forming a voltage converter on the facilitator die, the voltage converter coupled to the global power line and the local power line.

3. The method of claim 1, further comprising:
forming a global signal line coupled to the bottom die and the facilitator die in the first hierarchical level;
forming a local signal bus coupled to the facilitator die and one or more of the plurality of upper dies in the second hierarchical level; and
forming a serializer on the facilitator die, the serializer coupled to the global signal line and the local signal bus.

4. The method of claim 1, further comprising:
forming a common signal line comprising a fly-by-signal, the common signal line coupled to the bottom die and the facilitator die in the first hierarchical level; and
forming an electrostatic discharge (ESD) protection circuit on the facilitator die, the ESD protection circuit coupled to the common signal line.

5. The method of claim 1, wherein the first hierarchical level and the second hierarchical level comprise a redrive configuration.

6. The method of claim 1, wherein the first hierarchical level and the second hierarchical level comprise a two-level tree configuration.

7. The method of claim 1, wherein the first hierarchical level and the second hierarchical level comprise a both-end drive configuration.

8. The method of claim 1, further comprising forming a near memory processor on the facilitator die, the near memory processor configured to receive an execution code from the bottom die, process the execution code, and transmit memory data to an upper die of the plurality of upper dies.

9. The method of claim 1, further comprising forming a local memory on the facilitator die, the local memory configured to receive request and data signals from the bottom die.

10. The method of claim 1, further comprising forming a memory controller on the facilitator die, the memory controller configured to receive data from the bottom die, process the data, and transmit memory data to an upper die of the plurality of upper dies.

11. A semiconductor device comprising:
a plurality of stacked dies, the plurality of stacked dies comprising:
a bottom die comprising a first die type;
a plurality of upper dies comprising a second die type different than the first die type; and
a facilitator die comprising a third die type different than the first die type and the second die type; and
at least one of a signal connection and a power distribution line positioned hierarchically between the bottom die, the plurality of upper dies, and the facilitator die, wherein connections between the bottom die and the facilitator die comprise a first hierarchical level and connections between the facilitator die and one or more of the plurality of upper dies comprise a second hierarchical level.

12. The semiconductor device of claim 11, further comprising:
a global power line comprising a first voltage, the global power line coupled to the bottom die and the facilitator die in the first hierarchical level;
a local power line comprising a second voltage less than the first voltage, the local power line coupled to the facilitator die and one or more of the plurality of upper dies in the second hierarchical level; and
a voltage converter on the facilitator die, the voltage converter coupled to the global power line and the local power line.

13. The semiconductor device of claim 11, further comprising:
a global signal line coupled to the bottom die and the facilitator die in the first hierarchical level;
a local signal bus coupled to the facilitator die and one or more of the plurality of upper dies in the second hierarchical level; and
a serializer on the facilitator die, the serializer coupled to the global signal line and the local signal bus.

14. The semiconductor device of claim 11, further comprising:
a common signal line comprising a fly-by-signal, the common signal line coupled to the bottom die and the facilitator die in the first hierarchical level; and
an electrostatic discharge (ESD) protection circuit on the facilitator die, the ESD protection circuit coupled to the common signal line.

15. The semiconductor device of claim 11, wherein the first hierarchical level and the second hierarchical level comprise a redrive configuration.

16. The semiconductor device of claim 11, wherein the first hierarchical level and the second hierarchical level comprise a two-level tree configuration.

17. The semiconductor device of claim 11, wherein the first hierarchical level and the second hierarchical level comprise a both-end drive configuration.

18. The semiconductor device of claim 11, further comprising a near memory processor on the facilitator die, the near memory processor configured to receive an execution code from the bottom die, process the execution code, and transmit memory data to an upper die of the plurality of upper dies.

19. The semiconductor device of claim 11, further comprising a local memory on the facilitator die, the local memory configured to receive request and data signals from the bottom die.

20. The semiconductor device of claim 11, further comprising a memory controller on the facilitator die, the memory controller configured to receive data from the bottom die, process the data, and transmit memory data to an upper die of the plurality of upper dies.
